(19) United States
(12) Patent Application Publication
(10) Pub. No.: US 2009/0189136 A1
(43) Pub. Date: Jul. 30, 2009

(54) SEMICONDUCTOR DEVICE AND A MANUFACTURING METHOD OF THE SEMICONDUCTOR DEVICE

(75) Inventor: Nozomu Matsuzaki, Kodaira (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/359,594

(22) Filed: Jan. 26, 2009

(30) Foreign Application Priority Data
Jan. 28, 2008 (JP) JP 2008-16420

(51) Int. Cl. H01L 29/43; H01L 21/71; H01L 21/336

(52) U.S. Cl. 257/2; 438/675; 438/482; 365/163; 438/238; 257/E21.409; 257/E29.141; 257/E21.536

(57) ABSTRACT

A reliability of a semiconductor device having a phase-change memory is improved. A phase-change memory device has a bottom-electrode plug buried in an interlayer insulator that is provided on a main surface of a semiconductor substrate, an electric conductive material layer provided on an upper portion of the bottom-electrode plug and on the interlayer insulator, a phase-change material layer provided on the electric conductive material layer, and an upper-electrode plug provided on the phase-change material layer. The bottom-electrode plug and the upper-electrode plug which configure the phase-change memory device are provided at respective different positions in a plane of the semiconductor substrate.

### CROSS-REFERENCE TO RELATED APPLICATION

The present application claims priority from Japanese Patent Application No. JP 2008-016420 filed on Jan. 28, 2008, the content of which is hereby incorporated by reference into this application.

### TECHNICAL FIELD OF THE INVENTION

The present invention relates to a semiconductor device and a technique of manufacturing the semiconductor device. More particularly, the present invention relates to a technique effectively applied to a manufacture of a semiconductor device having a non-volatile memory (phase-change memory) formed of a phase-change material.

### BACKGROUND OF THE INVENTION

As one of non-volatile memories which retain data even when the power is turned off, a “phase-change memory” has been known. Phase-change memory memorizes data by a difference in its resistance value made by changing a crystalline state of a phase-change material (for example, a chalcogenide material) into either of an amorphous state or a polycrystalline state according to Joule heat.

U.S. Patent Publication No. US 2007/0123018 (Patent Document 1) discloses, for example in FIG. 2, a technique relating to a non-volatile memory (phase-change memory) having a memory layer (phase-change material layer) including a phase-change material. This phase-change memory has the memory layer including the phase-change material provided between a bottom electrode and an upper electrode, and uses the bottom electrode as a part of a heating element (so-called heater) in a writing of data. When a writing current is subjected to flow in the memory layer, a vicinity of a contact area between the memory layer and the bottom electrode is heated to be a phase-change region.

### SUMMARY OF THE INVENTION

The inventor of the present invention has studied about a semiconductor device that has a non-volatile memory (phase-change memory) formed of a phase-change material. A phase-change memory device (phase-change memory cell) that is a minimum unit to configure the phase-change memory which the present inventor has studied includes a MOSFET (Metal-Oxide-Semiconductor Field-Effect Transistor) that is a field-effect transistor and a resistor device that is electrically connected to the MOSFET. FIG. 1 is an explanatory diagram of a semiconductor device having the phase-change memory device which the present inventor has studied, and schematically shows a cross section of the resistor device that is provided on a semiconductor substrate and electrically connected to a MOSFET of n-type (n-channel type). Note that, in FIG. 1, the MOSFET is depicted by a symbol for simplicity.

The MOSFET that configures the memory device is formed with a gate electrode 1, a source electrode 2, and a drain electrode 3. The gate electrode 1 is electrically connected to a word line, the source electrode 2 is electrically connected to a source line, and the drain electrode 3 is electrically connected to the resistor device.

The resistor device that configures the memory device has: a bottom-electrode plug 15 that is buried in an interlayer insulator 4 that is provided on a main surface of a semiconductor substrate; a phase-change material layer (memory layer) 8 that is provided on an upper portion of the bottom-electrode plug 15 and on the interlayer insulator 4; an electric conductive material layer 9 that is provided on the phase-change material layer 8; and an upper-electrode plug 16 that is provided on the electric conductive material layer 9. The phase-change material layer 8 is, for example, a chalcogenide material formed of germanium, antimony, and tellurium to which indium and the like are added.

The bottom-electrode plug 15 is formed by burying an electric conductive material film 6 (e.g., tungsten) in the inside of a contact hole that is opened in the interlayer insulator 4 interposing a barrier metal film 5 formed of, for example, titanium nitride. And, the upper-electrode plug 16 is formed by burying an electric conductive material film 11 (e.g., tungsten) interposing a barrier metal film 10 formed of, for example, titanium nitride, and an electric conductive material film 11 (for example, tungsten) interposing a barrier metal film 10 in the inside of a contact hole opened in an interlayer insulator 7. The bottom-electrode plug 15 is electrically connected to the drain electrode 3, and the upper-electrode plug 16 is electrically connected to a wiring layer 12 to serve as a bit line.

A rewriting operation of the memory device which the present inventor has studied is performed by controlling heating (Joule heat) and cooling by energizing when setting the electric conductive material layer 9 (upper-electrode plug 16) side to a positive voltage and the bottom-electrode plug 15 side to a negative voltage to make the phase-change material layer 8 crystallized or amorphized. That heating is generated in a vicinity of a contact part between the phase-change material layer 8 and the bottom-electrode plug 15 to serve as a so-called heater, so that a change of crystallization and amorphization is made in the region (phase-change region). Note that, the fact that the phase-change region of the phase-change material layer 8 is on the bottom-electrode plug 15 side is same with the phase-change memory disclosed in the above-described Patent Document 1.

Here, more particularly, a method of forming the bottom-electrode plug 15 will be described. First, a contact hole is formed in the interlayer insulator 4, followed by forming the barrier metal film 5 in the inside of the contact hole and on the interlayer insulator 4. Next, the electric conductive material film 6 formed of, for example, tungsten is buried so as to fill the inside of the contact hole. Then, excess parts of the electric conductive material film 6 and the barrier metal film 5 are removed by a CMP (Chemical Mechanical Polishing) technique, and the interlayer insulator 4 is planarized, thereby forming the bottom-electrode plug 15 in the inside of the contact hole interposing the barrier metal film 5.

While the CMP technique is used to form the bottom-electrode plug 15 in this manner, as shown in FIG. 1, a recess (dent) 13 is created so that a pointed portion 14 is formed in a periphery of the plug. Therefore, when the rewriting operation of the memory device is performed, an electrical field concentration is caused at an edge portion of the recess 13 of the phase-change material layer 8, that is, the pointed portion 14, and so it is conceived that a current is prone to flow. FIG. 2 is an explanatory diagram of a result of EDX (Energy-Dispersive X-ray spectroscopy) on germanium in the phase-change material layer 8 after the rewriting operation. According to the EDX result, a distribution of a constituent element (for example, germanium) in the cross section of the phase-change memory device shown in FIG. 1 can be known.

According to the EDX result shown in FIG. 2, the phase-change material layer 8 is largely sectioned into three regions (regions 21, 22, and 23), and it has been revealed that the region 21 is in a relatively medium level in a germanium concentration, the region 22 has a relatively high germanium concentration, and the region 23 has a germanium concentration relatively low. Note that, in FIG. 2, hatching is applied to only the regions 21 and 23 for describing easier.

Since the region 22 exists on the pointed portion (a symbol 14 in FIG. 1) side of the bottom-electrode plug 15 and the germanium concentration of the region 23 in contact with the region 22 is lowered, it is considered that germanium in the region 23 is gathered in the vicinity of the pointed portion of the bottom-electrode plug 15 due to an electrical field concentration or a current concentration in the rewriting operation, thereby forming the region 22. That is, it is considered to cause a bias of an element that configures the phase-change material layer 8 when the pointed portion exists on the bottom-electrode plug 15. Such a bias of the constituent element can be a cause of deteriorating an original characteristic, that is, lowering of reliability.

An object of the present invention is to provide a technique capable of improving reliability of a semiconductor device having a phase-change memory.

The above and other objects and novel characteristics of the present invention will be apparent from the description of the present specification and the accompanying drawings.

The typical ones of the inventions disclosed in the present application will be briefly described as follows.

In an embodiment of the present invention, provided are: an interlayer insulator that is provided on a main surface of a semiconductor substrate; a bottom-electrode plug that is buried in the interlayer insulator; an electric conductive material layer that is provided on an upper portion of the bottom-electrode plug and on the interlayer insulator; a phase-change material layer that is provided on the electric conductive material layer; and an upper-electrode plug that is provided on the phase-change material layer, and the bottom-electrode plug and the upper-electrode plug are provided at respective different positions in a plane of the semiconductor substrate.

The effects obtained by typical aspects of the present invention will be briefly described below.

According to the embodiment, reliability of a semiconductor device having a phase-change memory can be improved.

### BRIEF DESCRIPTIONS OF THE DRAWINGS

FIG. 1 is an explanatory diagram of a semiconductor device having a phase-change memory device which the present inventor has studied;

FIG. 2 is an explanatory diagram of a result of EDX on germanium in a phase-change material layer after a rewriting operation;

FIG. 3 is an explanatory diagram of a semiconductor device having a phase-change memory according to an embodiment of the present invention;

FIG. 4 is a schematic diagram showing a cross section of a semiconductor device in a manufacturing step according to an embodiment of the present invention;

FIG. 5 is a schematic diagram showing a cross section of the semiconductor device in a manufacturing step continued from FIG. 4;

FIG. 6 is a schematic diagram showing a cross section of the semiconductor device in a manufacturing step continued from FIG. 5;

FIG. 7 is a schematic diagram showing a cross section of the semiconductor device in a manufacturing step continued from FIG. 6;

FIG. 8 is a schematic diagram showing a cross section of the semiconductor device in a manufacturing step continued from FIG. 7;

FIG. 9 is a schematic diagram showing a cross section of the semiconductor device in a manufacturing step continued from FIG. 8;

FIG. 10 is a schematic diagram showing a cross section of the semiconductor device in a manufacturing step continued from FIG. 9;

FIG. 11 is a schematic diagram showing a cross section of the semiconductor device in a manufacturing step continued from FIG. 10;

FIG. 12 is a schematic diagram showing a cross section of the semiconductor device in a manufacturing step continued from FIG. 11;

FIG. 13 is a schematic diagram showing a cross section of the semiconductor device in a manufacturing step continued from FIG. 12;

FIG. 14 is a schematic diagram showing a cross section of a semiconductor device in a manufacturing step according to another embodiment of the present invention;

FIG. 15 is a schematic diagram showing a cross section of the semiconductor device in a manufacturing step continued from FIG. 14;

FIG. 16 is a schematic diagram showing a cross section of the semiconductor device in a manufacturing step continued from FIG. 15;

FIG. 17 is a schematic diagram showing a cross section of the semiconductor device in a manufacturing step continued from FIG. 16;

FIG. 18 is a schematic diagram showing a cross section of the semiconductor device in a manufacturing step continued from FIG. 17;

FIG. 19 is a schematic diagram showing a cross section of the semiconductor device in a manufacturing step continued from FIG. 18;

FIG. 20 is a schematic diagram showing a cross section of the semiconductor device in a manufacturing step continued from FIG. 19;

FIG. 21 is a schematic diagram showing a cross section of a semiconductor device in a manufacturing step according to still another embodiment of the present invention;

FIG. 22 is a schematic diagram showing a cross section of the semiconductor device in a manufacturing step continued from FIG. 21;

FIG. 23 is a schematic diagram showing a cross section of the semiconductor device in a manufacturing step continued from FIG. 22;

FIG. 24 is a schematic diagram showing a cross section of the semiconductor device in a manufacturing step continued from FIG. 23;

FIG. 25 is a schematic diagram showing a cross section of the semiconductor device in a manufacturing step continued from FIG. 24;

FIG. 26 is a schematic diagram showing a cross section of the semiconductor device in a manufacturing step continued from FIG. 25; and

FIG. 27 is an explanatory diagram of a semiconductor device having a phase-change memory according to an embodiment of the present invention.

### DESCRIPTIONS OF THE PREFERRED EMBODIMENTS

Hereinafter, embodiments of the present invention will be described in detail with reference to the accompanying drawings. Note that, components having the same function are denoted by the same reference symbols throughout the drawings for describing the embodiment, and the repetitive description thereof may be omitted. Also, in the descriptions of embodiments of the present invention, a numerical value exemplifying a 0.13 μm process will be disclosed. However, a scope of the present invention is not limited to the disclosed value.

### First Embodiment

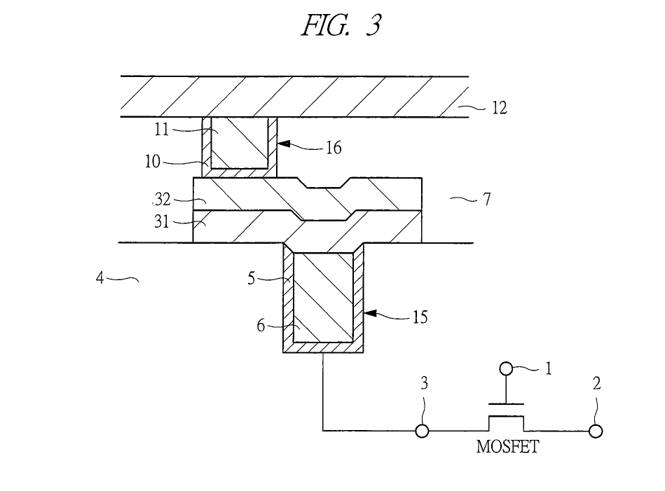

FIG. 3 is an explanatory diagram of a semiconductor device having a phase-change memory device according to an embodiment of the present invention, and schematically shows a cross section of a resistor device which is provided on a semiconductor substrate and electrically connected to an n-type MOSFET. Note that, in FIG. 3, the MOSFET is depicted by a symbol for simplicity.

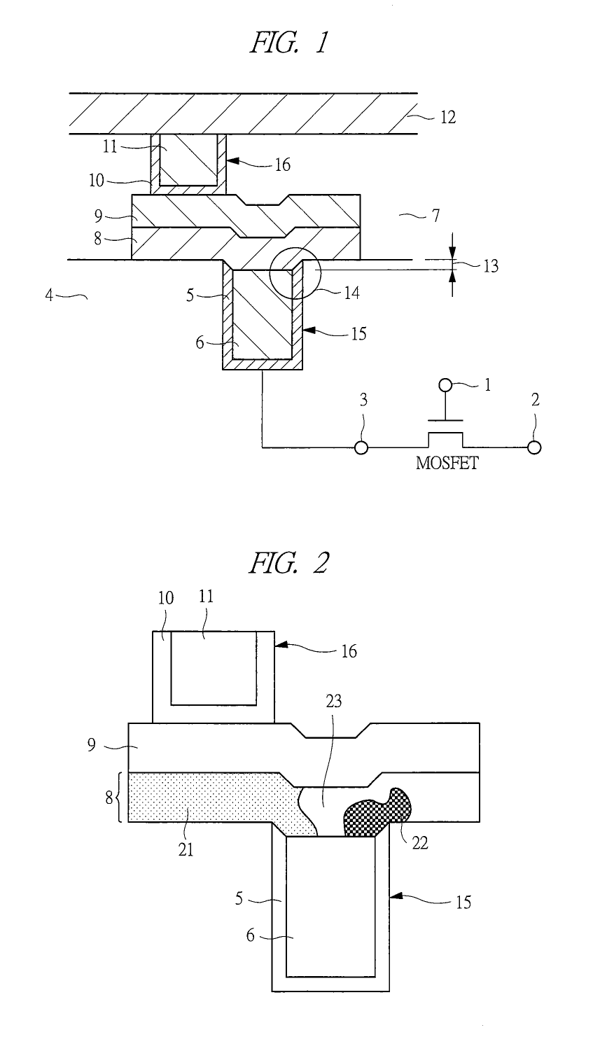

In the phase-change memory device of the semiconductor device according to the present embodiment, while the basic connecting relationship is similar to that shown in FIG. 1, it is different in a point of a layer structure in which a phase-change material layer 32 exists on an electric conductive material layer 31.

The phase-change memory device has; a bottom-electrode plug 15 that is buried into an interlayer insulator 4 that is provided on a main surface of a semiconductor substrate; an electric conductive material layer 31 that is provided on an upper portion of the bottom-electrode plug 15 and on the interlayer insulator 4; a phase-change material layer 32 that is provided on the electric conductive material layer 31; and an upper-electrode plug 16 that is provided on the phase-change material layer 32. The bottom-electrode plug 15 and the upper-electrode plug 16 configuring the phase-change memory device are provided at respective different positions in a plane of the semiconductor substrate. Further, the phase-change material layer 32 is, for example, a chalcogenide material formed of germanium, antimony, and tellurium to which indium and the like are added.

In this structure, an electrode forming a contact surface with the phase-change material layer 32 and having a contact surface to serve as a heat-generating part is the upper-electrode plug 16 that has the barrier metal film 10 and the electric conductive material film 11. The phase-change material layer 32 is provided between the upper-electrode plug 16 and the electric conductive material layer 31 serving as a bottom electrode, and a contact area between the upper-electrode plug 16 and the phase-change material layer 32 in an in-plane direction of the semiconductor substrate is smaller than a contact area between the electric conductive material layer 31 and the phase-change material layer 32. In this manner, the upper-electrode plug 16 has a contact surface to serve as the heat-generating part. Also, a rewrite part (phase-change region) in the phase-change material layer 32 is on the upper-electrode plug 16 side, and a resistance value of the phase-change material layer 32 can be changed by a phase change.

In addition, since the upper-electrode plug 16 is formed later than the phase-change material layer 32, there is no recess at a lower portion of the upper-electrode plug 16 in contact with the phase-change material layer 32. Note that, although the present embodiment shows a case that the upper-electrode plug 16 includes the barrier metal film 10, the upper-electrode plug 16 may not include the barrier metal film 10. Moreover, a connection between the upper-electrode plug 16 and the phase-change material layer 32 may interpose an interface layer formed of a metal oxide (such as tantalum oxide and chromium oxide).

Further, in a region of the phase-change material layer 32 existing immediately on the bottom-electrode plug 15 that has the barrier metal film 5 and the electric conductive material film 6, since a dent reflecting the recess on the upper portion of the bottom-electrode plug 15 is created, the upper-electrode plug 16 has to be provided so as to avoid the portion. Therefore, in FIG. 3, the upper-electrode plug 16 is provided on a portion where the phase-change material layer 32 is flat.

In this manner, since a pointed portion is not created on the upper-electrode plug 16 in contact with the phase-change material layer 32, a bias of the constituent element as described with reference to FIG. 2 is less prone to occur. Therefore, a deterioration of an original characteristic can be prevented, so that reliability of the semiconductor device is improved. That is, since a current concentration to the pointed portion of the electrode that has a contact surface to serve as the heat-generating portion can be reduced, it can be expected that the bias of the component element that configures the phase-change material is suppressed. In that manner, a stable phase-change memory device that has a small characteristic variation can be realized.

### Second Embodiment

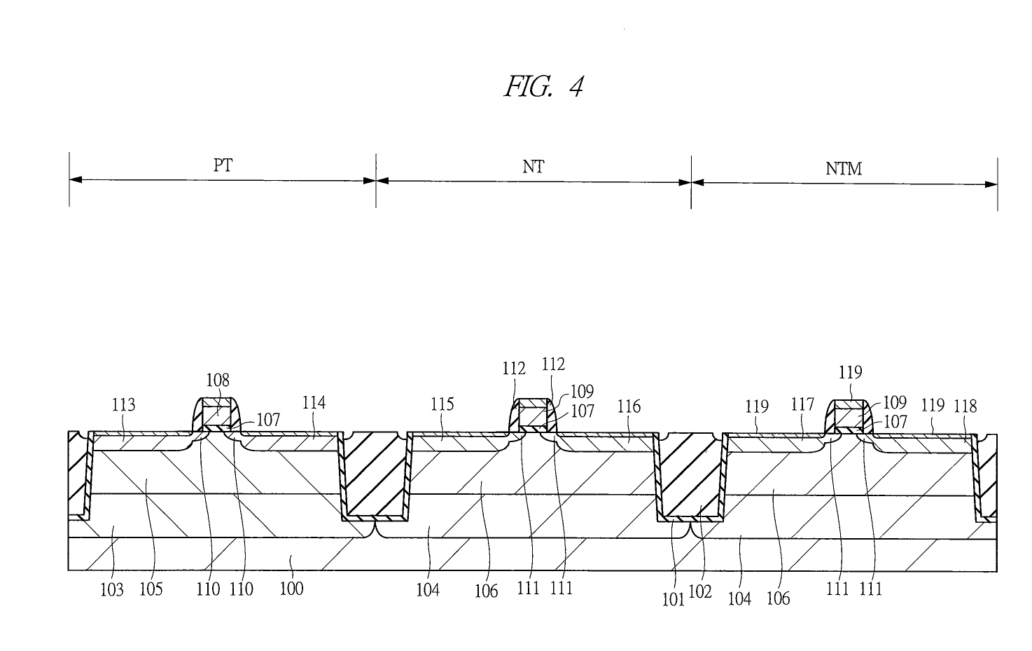

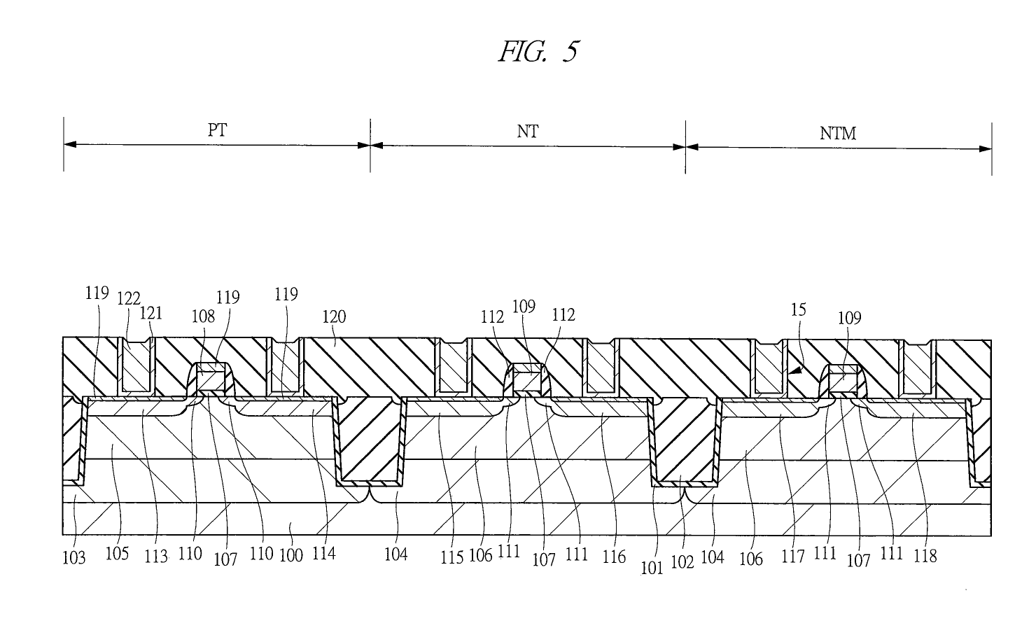

A manufacturing method of a semiconductor device having a phase-change memory in a manufacturing process according to the present embodiment will be described with reference to FIGS. 4 to 13. FIGS. 4 to 13 are schematic diagrams showing a cross section of the semiconductor device having the phase-change memory in the manufacturing process according to the present embodiment. Note that, in these figures, “NT” indicates a region where an n-type MOSFET is formed, “PT” indicates a region where a p-type MOSFET is formed, and “NTM” indicates a region where a phase-change memory device (phase-change memory cell) is formed.

First, as shown in FIG. 4, on a main surface of a semiconductor substrate 100 formed of, for example, a p-type single-crystal silicon substrate, formed are an n-type MOSFET in the region NT, a p-type MOSFET in the region PT, and an n-type MOSFET in the region NTM. The n-type MOSFET formed in the region NT and the p-type region formed in the region PT configure a CMOS (Complementary MOS), and the n-type MOSFET formed in the region NTM configures the phase-change memory device such as shown in, for example, FIG. 3.

Constituent components in FIG. 4 are: 101 indicating a liner layer under an isolation oxide; 102 indicating the isolation oxide; 103 indicating an n-type buried well; 104 indicating a p-type buried well; 105 indicating an n-type well; 106 indicating a p-type well; 107 indicating a gate oxide film; 108 indicating a p-type gate electrode; and 109 indicating an n-type gate electrode. Also, 110 indicates a shallow-junction p-type diffusion layer; 111 indicates a shallow-junction n-type diffusion layer; 112 indicates a gate-electrode sidewall spacer; 113 indicates a p-type drain diffusion layer; 114 indicates a p-type source diffusion layer; 115 indicates an n-type drain diffusion layer; 116 indicates an n-type source diffusion layer; 117 indicates an n-type drain diffusion layer of an n-type MOSFET for the phase-change memory device; 118 indicates an n-type source diffusion layer of a n-type MOSFET for the phase-change memory device; and 119 indicates a Co (cobalt) salicide layer.

Main size of each constituent element will be shown. A depth of a device isolation formed of the liner layer under the isolation oxide 101 and the isolation oxide 102 is, for example, 350 nm. And, impurity concentrations of the n-type buried well 103, the p-type buried well 104, the n-type well 105, and the p-type well 106 are about 10 to the power of 17 number of atoms per one cubic centimeter. In addition, a thickness of the gate oxide film 107 is, for example, 3.5 nm. Moreover, thicknesses of the p-type gate electrode 108 and the n-type gate electrode 109 are, for example, 150 nm, and gate lengths thereof are 130 nm. Further, a width of the gate-electrode sidewall spacer 112 (in horizontal direction in FIG. 4) is, for example, 70 nm.

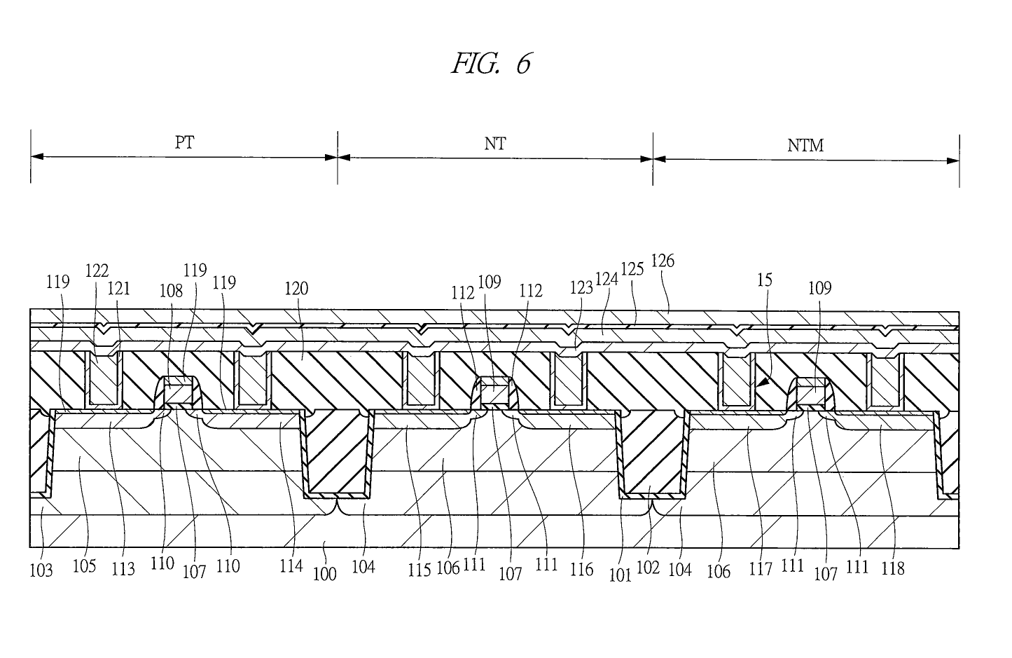

Subsequently, as shown in FIG. 5, an interlayer insulator 120 formed of, for example, silicon oxide film is deposited on the main surface of the semiconductor substrate 100 by using a CVD (Chemical Vapor Deposition) technique, followed by forming a contact hole having a diameter of, for example, 180 nm on the interlayer insulator 120 by using a known photolithography and a dry-etching technique.

Next, a barrier metal film 121 formed of, for example, titanium nitride is deposited in the inside of the contact hole and on the interlayer insulator 120 by using a CVD technique followed by burying an electric conductive material film 122 formed of, for example, tungsten in the contact hole by using a CVD technique, and then, unnecessary parts of the electric conductive material film 122 and the barrier metal film 121 are removed by a CMP technique, so that the interlayer insulator 120 is planarized, and also an electrode plug including the barrier metal film 121 and the electric conductive film 122 is formed in the contact hole. A diameter of the electrode plug is, for example, 180 nm. Note that, an electrode plug to be electrically connected to a drain of the n-type MOSFET in the region NTM becomes the bottom-electrode plug 15 configuring the phase-change memory device. Further, as described above, the recess (dent) is formed, so that an upper portion of the bottom-electrode plug 15 is dented.

Subsequently, as shown in FIG. 6, an electric conductive material layer 123 is formed on an upper potion of the electrode plug (including the bottom-electrode plug 15) and on the interlayer insulator 120 followed by forming a phase-change material layer 124 on the electric conductive material layer 123. Next, an interface layer 125 is formed on the phase-change material layer 124 followed by forming an electric conductive material layer 126. As respective materials, titanium nitride is used for the electric conductive material layer 123, a chalcogenide material formed of germanium, antimony, and tellurium to which indium and the like are added is used for the phase-change material layer 124, a metal oxide (such as tantalum oxide and chromium oxide) is used for the interface layer 125, and an electric conductive material (such as tungsten and titanium nitride) is used for the electric conductive material layer 126. A thickness of the electric conductive material layer 123 is, for example, 30 nm, and a thickness of the phase-change material layer 124 is, for example, 100 nm. The interface layer 125 is an important constituent component for improving an adhesion property between the phase-change material layer 124 and the electric conductive material layer 126, and a thickness thereof is less than or equal to 5 nm. A thickness of the electric conductive material layer 126 is, for example, 50 nm.

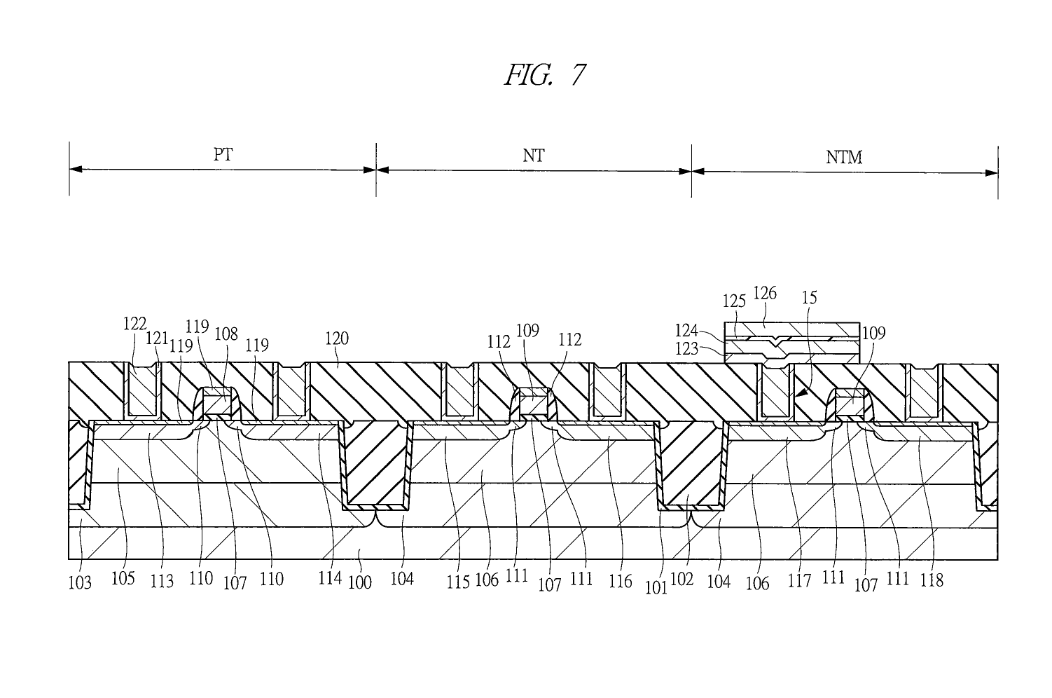

Subsequently, as shown in FIG. 7, patterning is performed so as to remain the electric conductive material layer 126, the interface insulator 125, the phase-change material layer 124 and the electric conductive material layer 123 on an upper portion of the bottom-electrode plug 15 in the region NTM by using a photolithography technique and a dry-etching technique. Note that, the phase-change material layer 124 corresponds to the phase-change material layer 32 shown in FIG. 3, and the electric conductive material layer 123 corresponds to the electric conductive material layer 31 (bottom electrode) shown in FIG. 3.

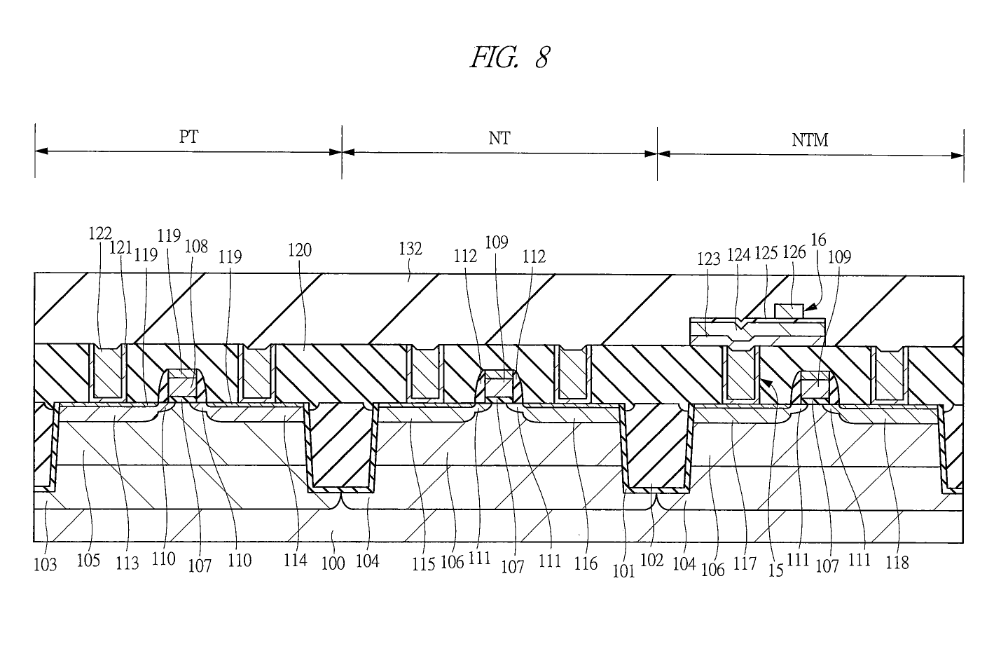

Subsequently, as shown in FIG. 8, patterning is performed so as to remain a part of the electric conductive material layer 126 by using a photolithography technique and a dry-etching technique, so that an upper-electrode plug 16 is formed on the phase-change material layer 124 interposing the interface layer 125 and at a position different from the bottom-electrode plug 15 in the plane of the semiconductor substrate 100. When the electric conductive material layer 126 is processed by a dry-etching technique to form the upper-electrode plug 16, if selectivity of the electric conductive material film with respect to the interface layer 125 is sufficiently high, the interface layer 125 can be used as an etching-stopper layer.

In this manner, the upper-electrode plug 16 is provided on a flat portion of a stacked film of the electric conductive material layer 123, the phase-change material layer 124, and the interface layer 125. In other words, the bottom-electrode plug 15 and the upper-electrode plug 16 do not overlap to each other in the plane of the semiconductor substrate 100. Therefore, it is possible to make a structure in which a contact surface between the upper-electrode plug 16 and the phase-change material layer 124 is flat and the recess does not occur on the upper-electrode plug 16 that has a contact surface to serve as the heat-generating portion. Consequently, an electric field concentration that occurs at an edge portion (pointed portion) of the recess can be avoided, thereby preventing a bias of the constituent component of the phase-change material layer 124.

The phase-change material layer 124 is provided between the upper-electrode plug 16 and the electric conductive material layer 123 serving as the bottom electrode, and as recognized from the abovedescribed manufacturing process, the contact area between the upper-electrode plug 16 and the phase-change material layer 124 in an in-plane direction of the semiconductor substrate 100 is smaller than the contact area between the electric conductive material layer 123 and the phase-change material layer 124. In this manner, the upper-electrode plug 16 can be taken as an electrode that has a contact surface to serve as the heat-generating portion. Further, a rewrite portion (phase-change region) in the phase-change material layer 124 is on the upper-electrode plug 16 side, thereby changing the resistance value of the phase-change material layer 124 by a phase change.

More particularly, a size of the upper-electrode plug 16 will be described. In a phase-change memory device, the smaller a contact area between a rewriting portion and an electrode is, the smaller a rewriting current of the phase-change device is. Therefore, the size of the upper-electrode plug 16 can be set so as to satisfy a desired rewriting current. For example, as the present embodiment, when the interface layer 125 is used, an electrode diameter can be 160 nm for the rewriting current of 100 μA or less.

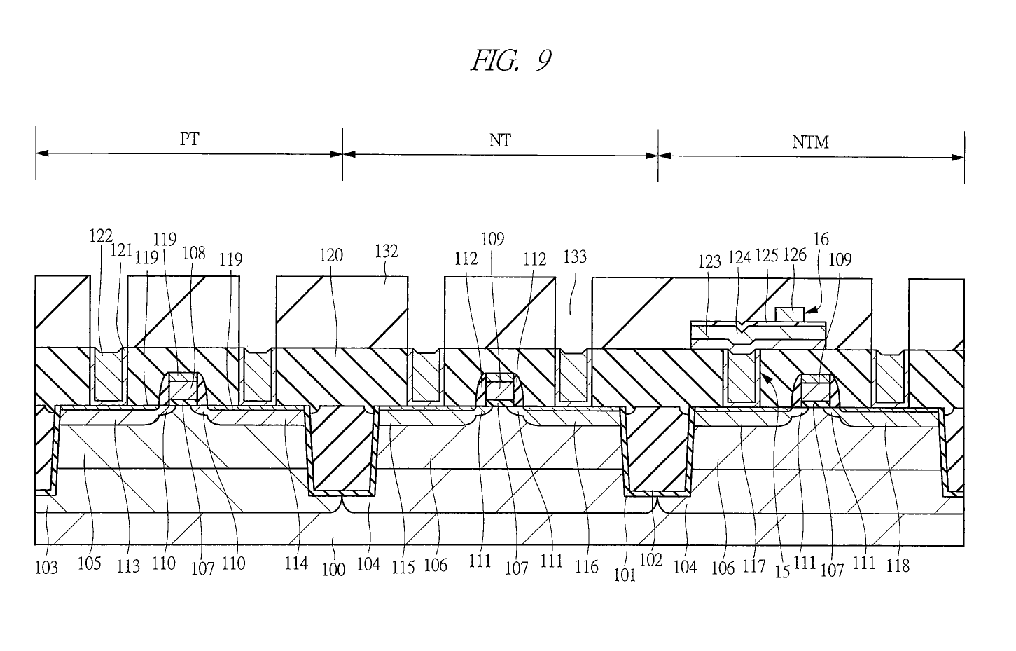

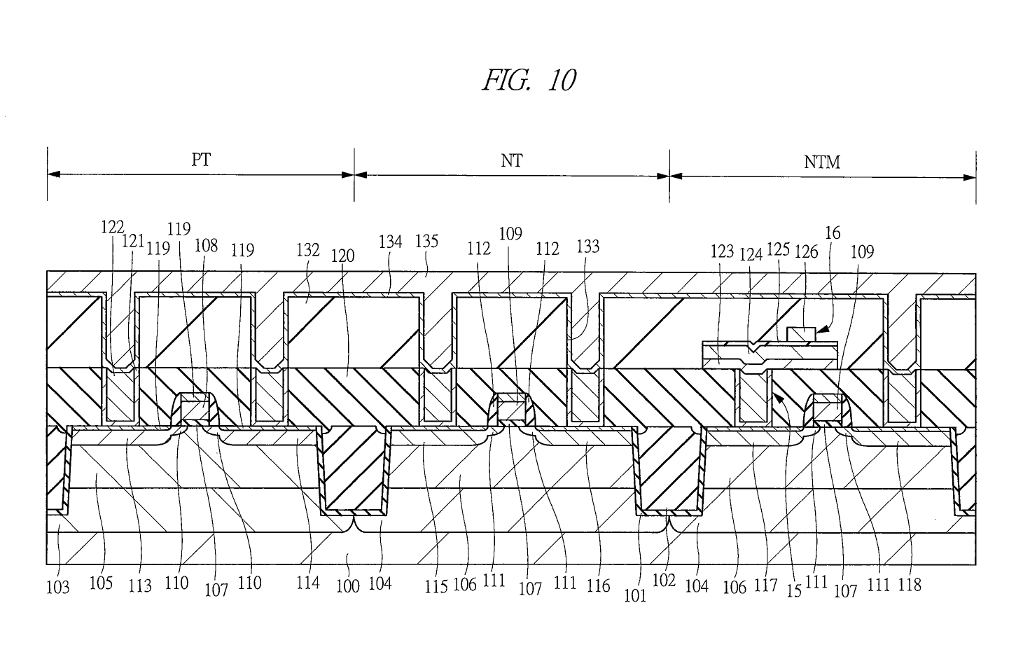

Subsequently, an interlayer insulator 132 formed of, for example, a silicon oxide film is deposited on the main surface of the semiconductor substrate 100 followed by forming, as shown in FIG. 9, a contact hole 133 in the interlayer insulator 132 by using a photolithography technique and a dry-etching technique. Note that, in the present embodiment, while a structure is disclosed in which a contact hole is added on a previously formed electrode plug (except for the bottom-electrode plug 15), a manufacturing method can be also taken in which the contact hole for forming the electrode plug is provided on a Co salicide layer 119 for the first time at the stage of FIG. 9. This manner requires a smaller number of times of the CMP compared to the method of previously forming the electrode plug, thereby reducing manufacturing cost.

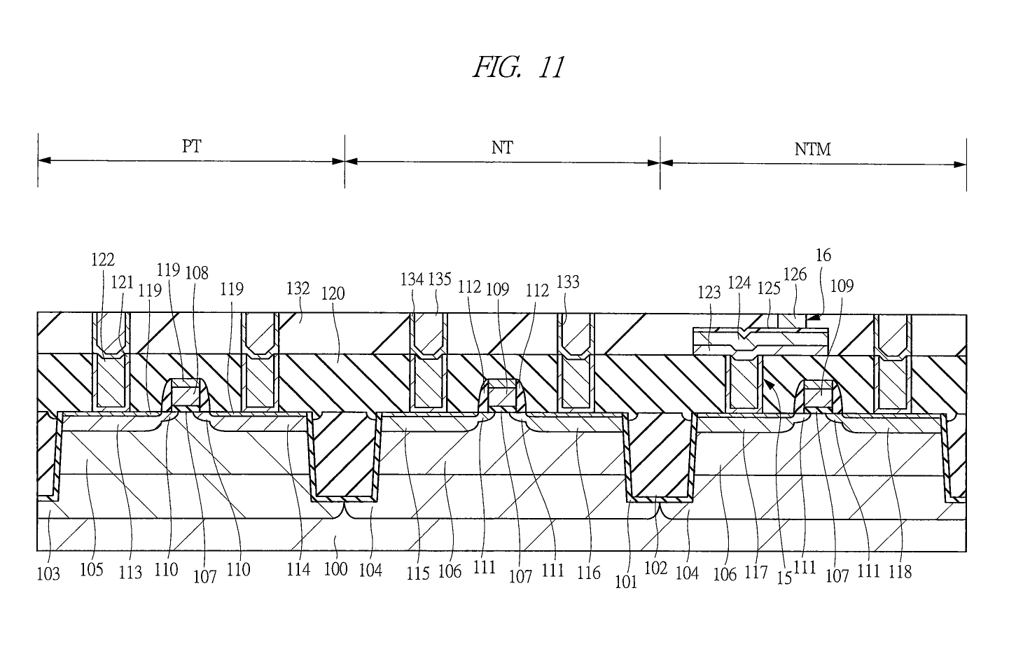

Subsequently, as shown in FIG. 10, a titanium nitride film 134 is deposited in the inside of the contact hole 133 and on the interlayer insulator 132 by using a sputtering method, followed by depositing a tungsten film 135 on the titanium nitride film 134 so as to fill the inside of the contact hole 133 by using a CVD method. A thickness of the titanium nitride 134 is 20 nm, and a thickness of the tungsten film 135 is about 150 to 200 nm. It is necessary to completely fill the contact hole 133.

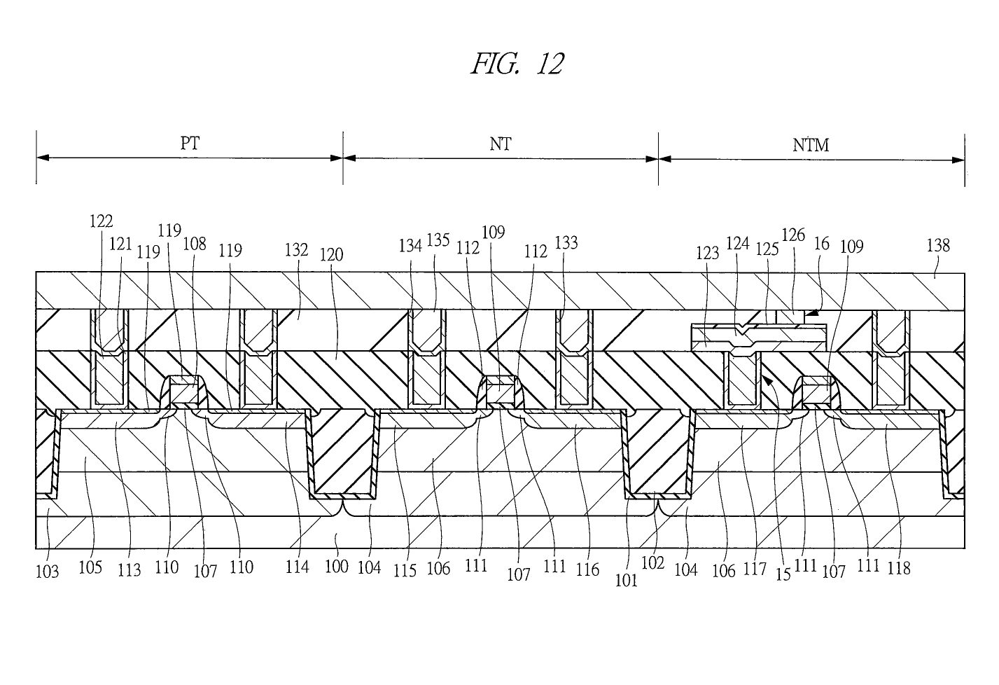

Subsequently, as shown in FIG. 11, the tungsten film 135 and the titanium nitride film 134 are removed by a CMP technique until the upper-electrode plug 16 is exposed. At this time, a plug electrode configured with the titanium nitride film 134 and the tungsten film 135 that are buried in the contact hole 133 is formed.

Subsequently, as shown in FIG. 12, a metal layer 138 is deposited on the main surface of the semiconductor substrate 100. This metal layer 138 can be the one that is used for known wiring-layer formation techniques, and aluminum is generally used. However, a copper wiring using a known damascene technique can be also used. Herein, an example using an aluminum wiring will be described.

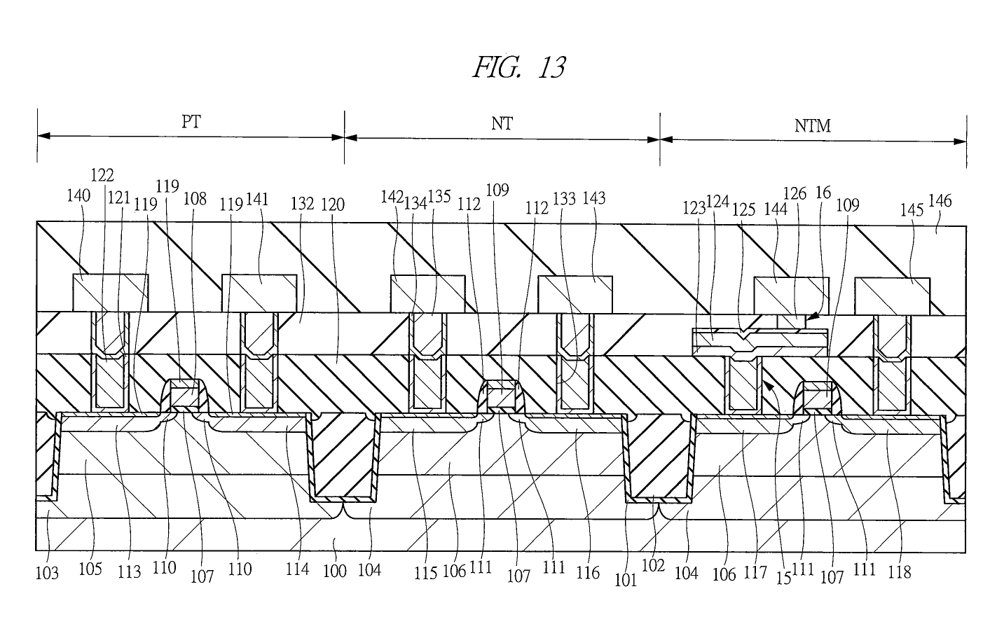

Subsequently, as shown in FIG. 13, the metal layer 138 is subjected to a patterning process, so that wiring layers corresponding to respective terminals are formed. That is, the patterned metal layers 138 become a drain line 140 of the p-type MOSFET, a source line 141 of the p-type MOSFET, a drain line 142 of the n-type MOSFET, a source line 143 of the n-type MOSFET, a bit line 144 to be connected to the upper-electrode plug 16 of the phase-change memory device, and a source line 145 of the n-type MOSFET configuring the phase-change memory device, respectively.

Next, an interlayer insulator 146 formed of a silicon oxide film is deposited on the main surface of the semiconductor substrate 100 by using, for example, a CVD method. In this manner, the phase-change memory device according to the embodiment of the present invention can be formed on a CMOS-LSI. Note that, while the wiring layer is formed with not only one layer but normally two or three layers, only one layer has been disclosed in the present embodiment to avoid a complication of drawings.

### Third Embodiment

To form of the upper-electrode plug in the abovedescribed first embodiment, the abovedescribed second embodiment has described the case where the electric conductive material layer on the phase-change material layer is patterned to form the upper-electrode plug. Meanwhile, a present embodiment will describe a case that a contact hole is formed in a stacked film formed by depositing a silicon oxide layer and a silicon nitride layer in this order on a phase-change material layer, followed by forming an upper-electrode plug in the contact hole. Note that, when other configurations and the like are same with the second embodiment, the descriptions of the same may be omitted.

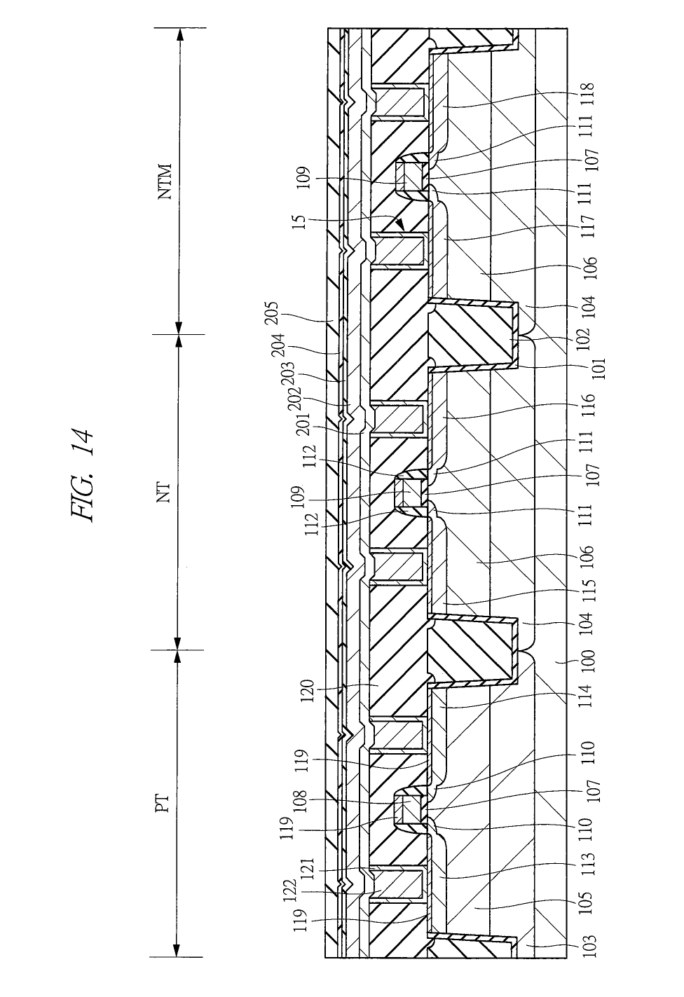

A manufacturing method of a semiconductor device having a phase-chance memory in a manufacturing process according to the present embodiment will be described with reference to FIGS. 14 to 20. FIGS. 14 to 20 are schematic diagrams showing a cross section of the semiconductor device having the phase-change memory in the manufacturing process according to the present embodiment. Note that, in the present embodiment, a step continued from the step that has been described with reference to FIG. 5 in the second embodiment will be first described.

As shown in FIG. 14, an electric conductive material layer 201 is deposited on the interlayer insulator 120 and on an upper portion of the electrode plug (including the bottom-electrode plug 15) that is formed of the barrier metal film 121 and the electric conductive material film 122, followed by depositing a phase-change material layer 202 on the electric conductive material layer 201. Next, an interface layer 203 is deposited on the phase-change material layer 202, followed by depositing a silicon oxide layer 204 and a silicon nitride layer 205 in this order to form a stacked film on the phase-change material layer 202 interposing the interface layer 203. Note that, the electric conductive material layer 201, the phase-change material layer 202, and the interface layer 203 correspond to the electric conductive material layer 123, the phase-change material layer 124, and the interface layer 125 in the second embodiment, respectively (refer to FIG. 6).

A thickness of the silicon oxide layer 204 is, for example, 15 nm, and a thickness of the silicon nitride layer 205 is, for example, 100 nm. The silicon oxide layer 204 and the silicon nitride layer 205 has a stacked structure that will be required in an electrode connection processing to the phase-change device portion, and a detail thereof will be described later.

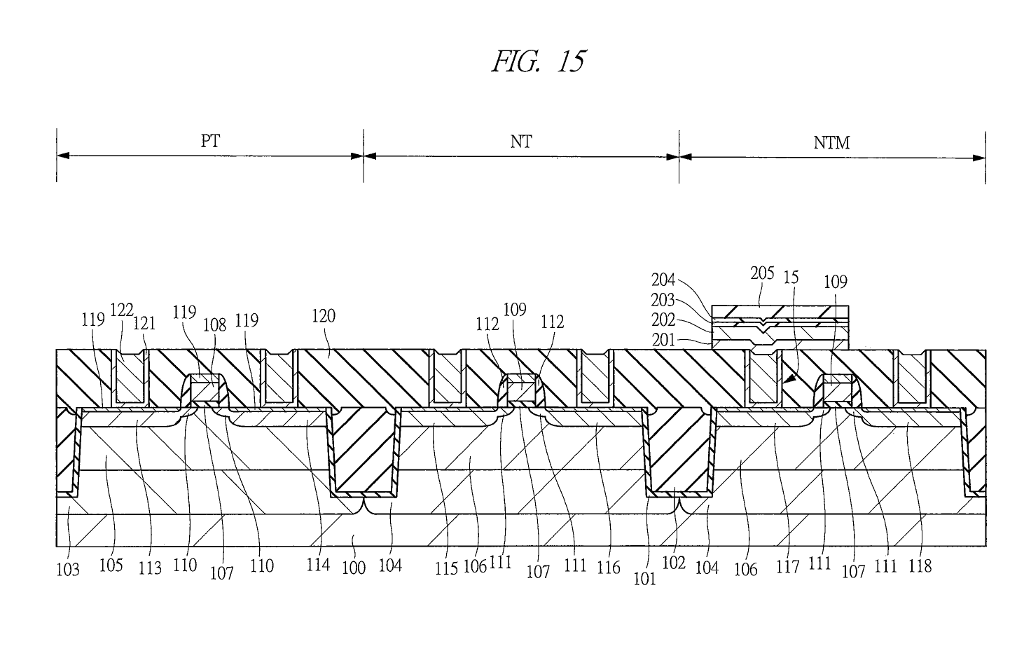

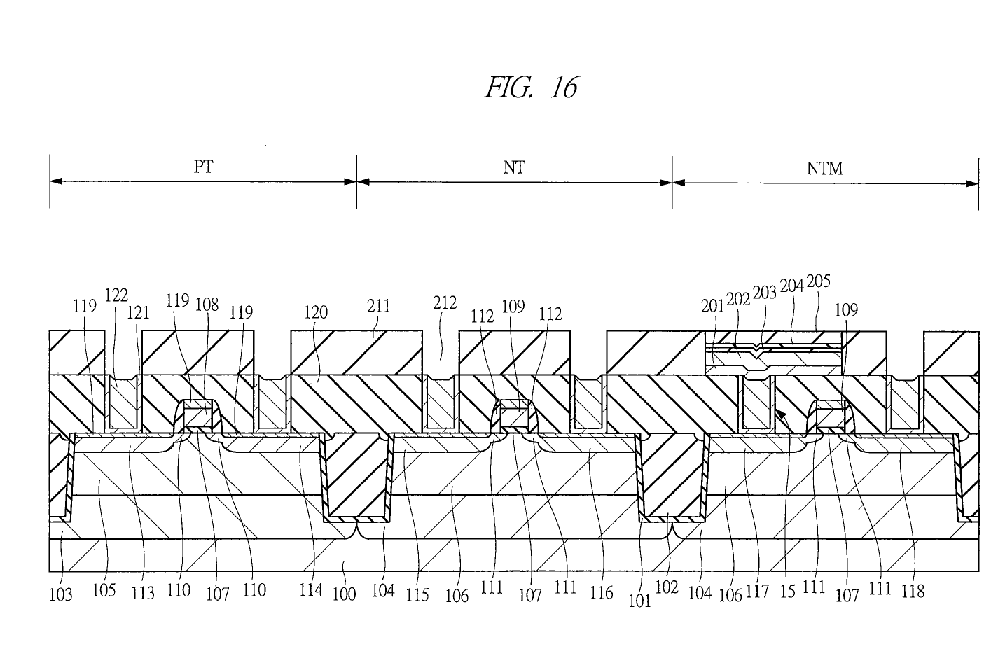

Subsequently, as shown in FIG. 15, patterning is performed so as to remain the silicon nitride layer 205, the silicon oxide layer 204, the interface layer 203, the phase-change material layer 202, and the electric conductive material layer 201 on an upper portion of the bottom-electrode plug 15 in the region NTM by using a photolithography technique and a dry-etching technique.

Subsequently, as shown in FIG. 16, an interlayer insulator 211 is deposited on the main surface of the semiconductor substrate 100, followed by exposing the silicon nitride layer 205 by performing a CMP technique, and then a contact hole 212 is formed by using a photolithography technique and a dry-etching technique. Normally, a silicon oxide film is used for the interlayer insulator 211. Also, the silicon nitride layer 205 functions as a stopper layer when the CMP is performed on the interlayer insulator 211.

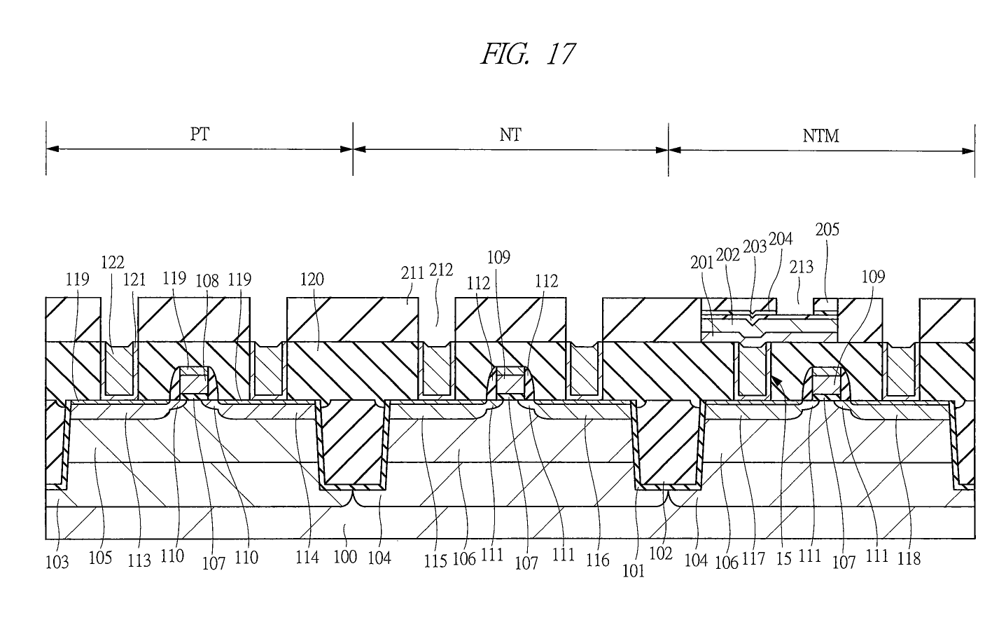

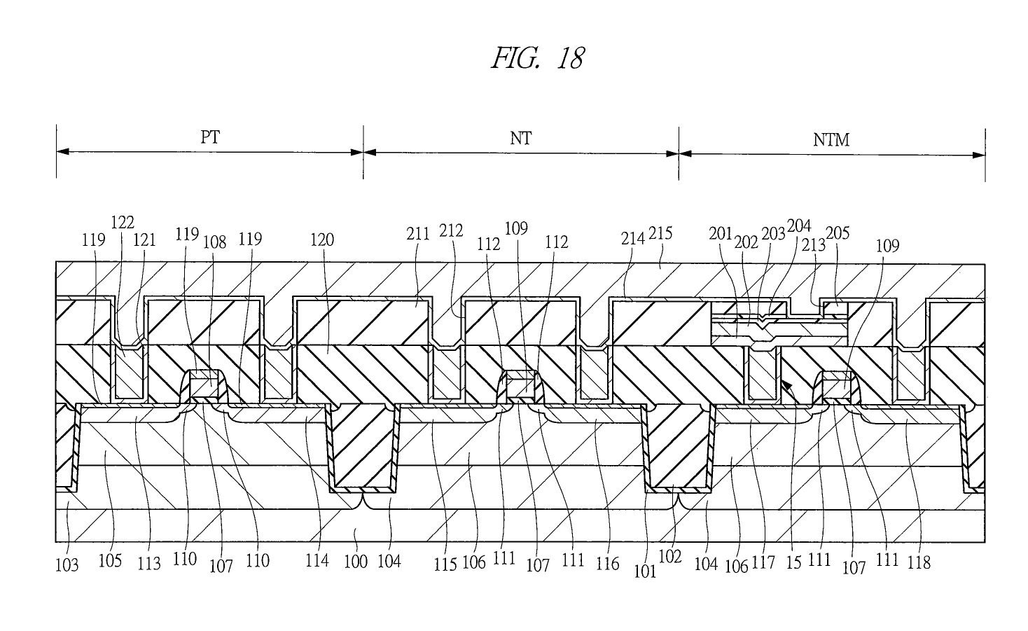

Subsequently, as shown in FIG. 17, a contact hole 213 is formed in the silicon oxide layer 204 and the silicon nitride layer 205 on the phase-change material layer 202 so as to expose the interface layer 203. In a method of forming the contact hole 213, first, only the silicon nitride layer 205 is removed by using a photolithography technique and a dry-etching technique. Next, if dry etching is applied when the silicon oxide layer 204 is removed, the interface layer 203 gets damaged due to plasma. So, herein, a method of removing the silicon oxide layer 204 by using hydrofluoric acid is applied. According to this method, the silicon oxide layer 204 can be removed without etching the interface layer 203 formed of a metal oxide film.

Subsequently, as shown in FIG. 18, a barrier metal film 214 formed of, for example, titanium nitride is formed in the inside of the contact holes 212 and 213 and on the interlayer insulator 211, followed by depositing an electric conductive material film 215 formed of, for example, tungsten so as to fill the inside of the contact holes 212 and 213. The deposition of titanium nitride is desired to use a sputtering method capable of processing in a lower temperature than that of a CVD, and the deposition of tungsten is desired to use a CVD having a good filling property.

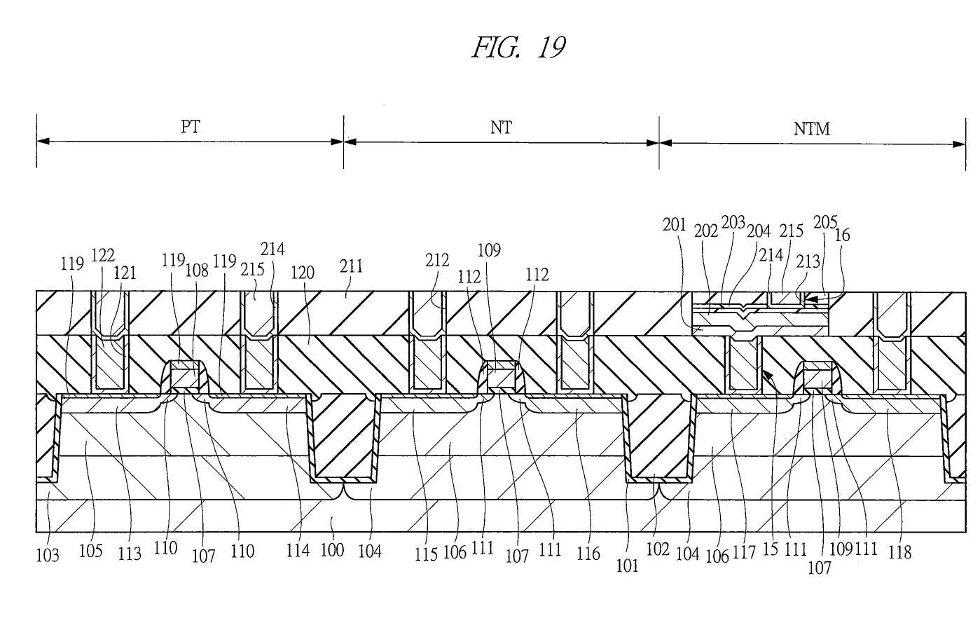

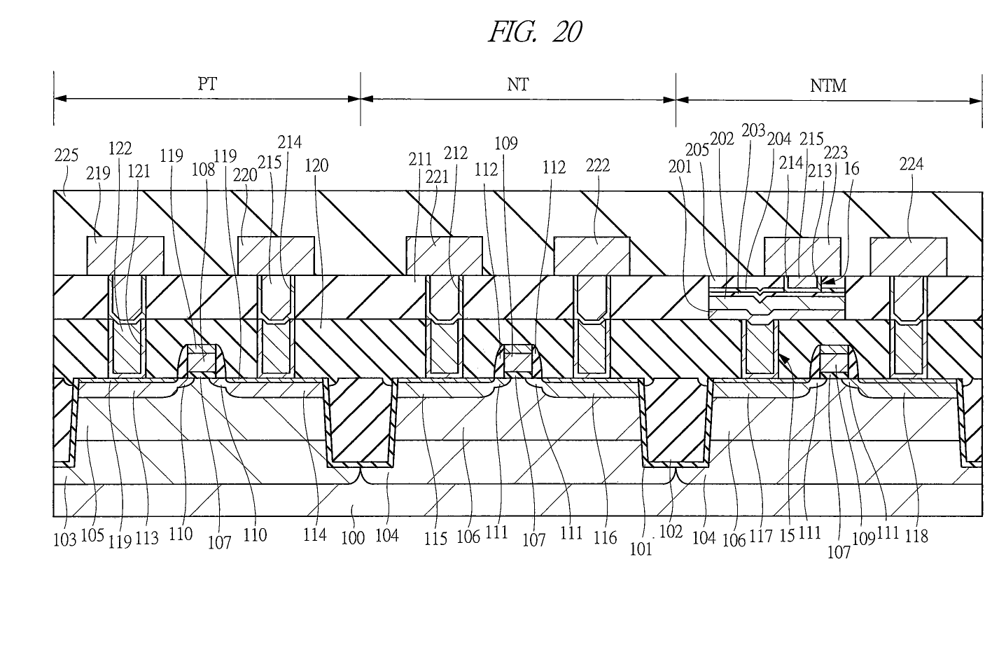

Subsequently, as shown in FIG. 19, unnecessary parts of the electric conductive material film 215 and the barrier metal film 214 are removed by a CMP technique until the silicon nitride layer 205 is exposed, so that the interlayer insulator 211 is planarized, and also the upper-electrode plug 16 including the barrier metal film 214 and the electric conductive material film 215 is formed in the contact hole 213. Note that, a diameter of the upper-electrode plug 16 is, for example, 160 nm.

Subsequently, as shown in FIG. 20, a metal layer formed of, for example, aluminum is deposited on the main surface of the semiconductor substrate 100, and the metal layer is subjected to a patterning work, so that wiring layers corresponding to respective terminals are formed. That is, the patterned metal layers become a drain line 219 of the p-type MOSFET, a source line 220 of the p-type MOSFET, a drain line 221 of the n-type MOSFET, a source line 222 of the n-type MOSFET, a bit line 223 to be connected to the upper-electrode plug 16 of the phase-change memory device, and a source line 224 of n-type MOSFET configuring the phase-change memory device, respectively.

Next, an interlayer insulator 225 formed of a silicon oxide film is deposited on the main surface of the semiconductor substrate 100 by using, for example, a CVD method. In this manner, the phase-change memory device according to the embodiment of the present invention can be formed on a CMOS-LSI. Note that, while the wiring layer is formed by not only one layer but normally two or three layers, only one layer has been disclosed in the present embodiment to avoid a complication of drawings.

### Fourth Embodiment

To form the upper-electrode plug of the abovedescribed first embodiment, the abovedescribed second embodiment has described the case that the electric conductive material layer on the phase-change material layer is patterned to form the upper-electrode plug. Meanwhile, a present embodiment will describe a case that a contact hole is formed in a stacked film formed by depositing a silicon nitride layer and a silicon oxide layer in this order on a phase-change material layer, followed by forming the upper-electrode plug in the contact hole. Note that, when other configurations and the like are same with the second embodiment, the descriptions of the same may be omitted.

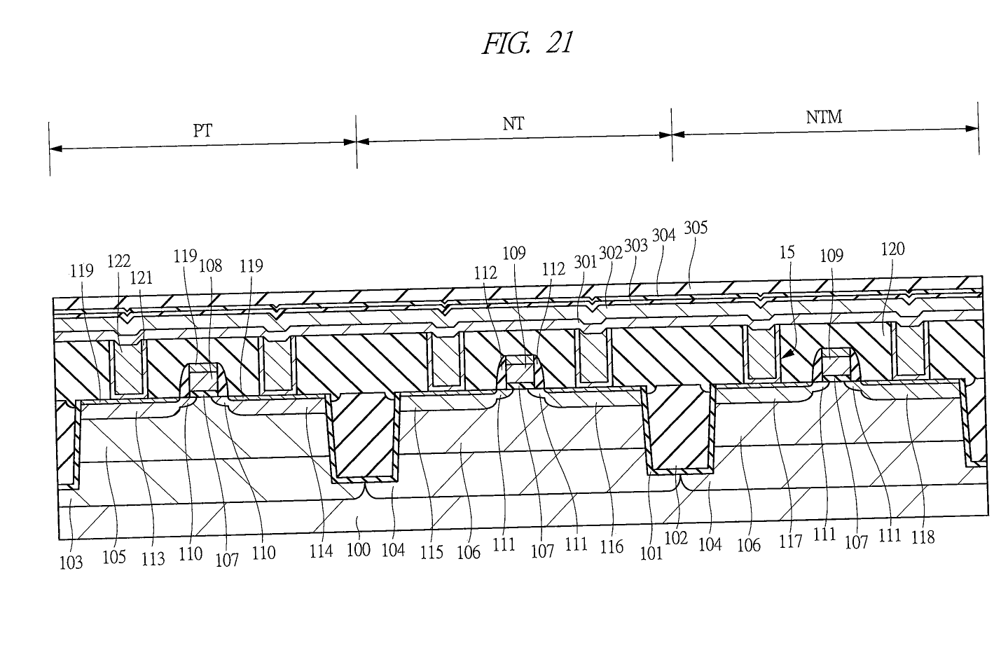

A manufacturing method of a semiconductor device having a phase-chance memory in a manufacturing process according to the present embodiment will be described with reference to FIGS. 21 to 26. FIGS. 21 to 26 are schematic diagrams showing a cross section of the semiconductor device having the phase-change memory in the manufacturing process according to the present embodiment. Note that, in the present embodiment, a step continued from the step that has been described with reference to FIG. 5 in the second embodiment will be first described.

As shown in FIG. 21, an electric conductive material layer 301 is deposited on the interlayer insulator 120 and on an upper portion of the electrode plug that is formed of the barrier metal film 121 and the electric conductive material film 122, followed by depositing a phase-change material layer 302 on the electric conductive material layer 301. Next, an interface layer 303 is deposited on the phase-change material layer 302, followed by depositing a silicon nitride layer 304 and a silicon oxide layer 305 in this order to form a stacked film on the phase-change material layer 302 interposing the interface layer 303. Note that, the electric conductive material layer 301, the phase-change material layer 302, and the interface layer 303 correspond to the electric conductive material layer 123, the phase-change material layer 124, and the interface layer 125 in the second embodiment, respectively (refer to FIG. 6).

A thickness of the silicon nitride layer 304 is, for example, 15 nm, and a thickness of the silicon oxide layer 305 is, for example, 100 nm. Note that, a stacked structure of the stacked films is different from that of the abovedescribed third embodiment, in which the silicon oxide layer 305 is the uppermost layer and the silicon nitride layer 304 is positioned immediately under the silicon oxide layer 305. A reason thereof will be apparent from descriptions of the following steps.

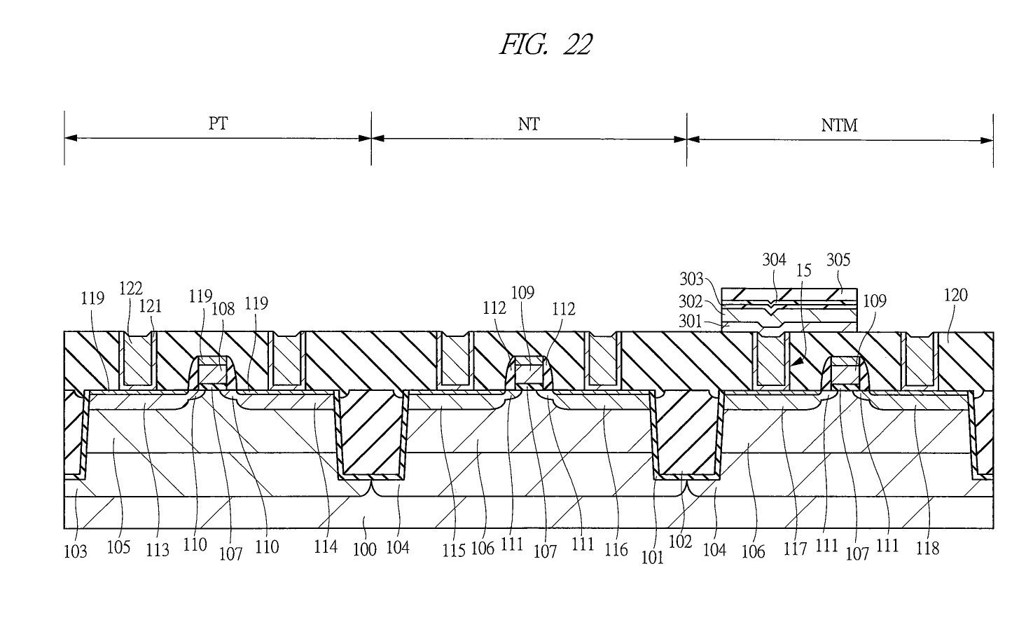

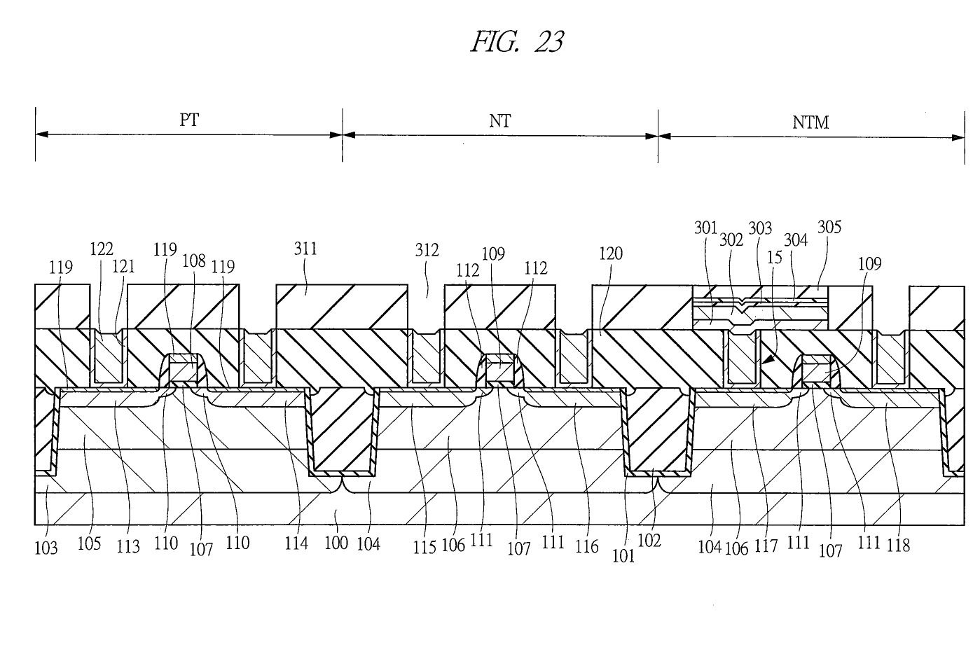

Subsequently, as shown in FIG. 22, patterning is performed so as to remain the silicon oxide layer 305, the silicon nitride layer 304, the interface layer 303, the phase-change material layer 302, and the electric conductive material layer 301 on the upper portion of the bottom-electrode plug 15 in the region NTM by using a photolithography technique and a dry-etching technique.

Subsequently, as shown in FIG. 23, an interlayer insulator 311 is deposited on the main surface of the semiconductor substrate 100, followed by exposing the silicon oxide layer 305 by performing a CMP technique, and then, a contact hole 312 is formed by using a photolithography technique and a dry-etching technique. Normally, a silicon oxide film is used for the interlayer insulator 311.

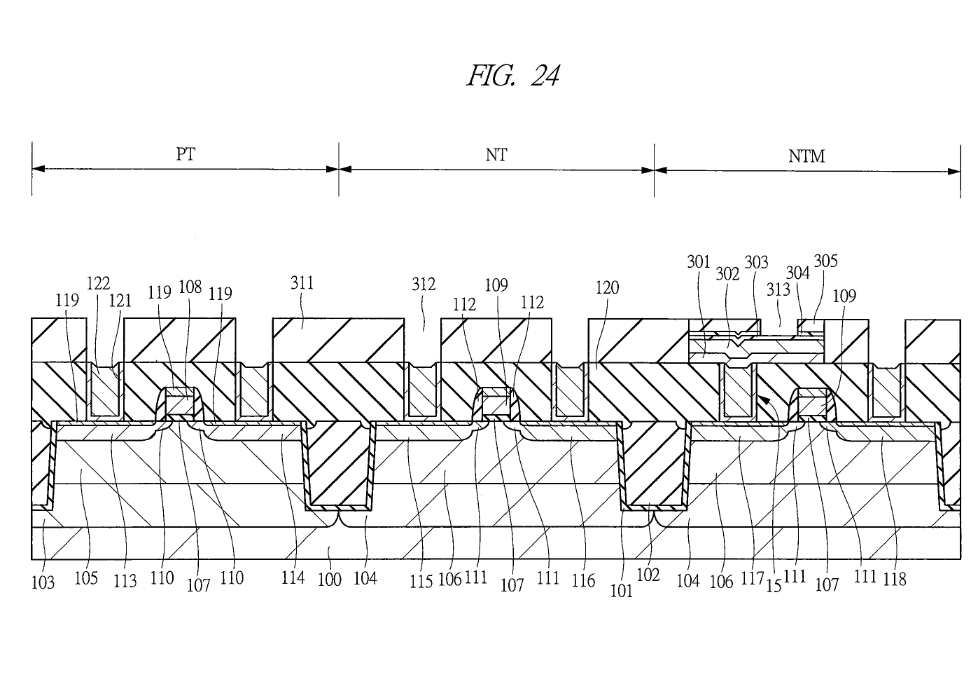

Subsequently, as shown in FIG. 24, a contact hole 313 is formed in the silicon oxide layer 305 and the silicon nitride layer 304 on the phase-change material layer 302 so as to expose the interface layer 303. In a method of forming the contact hole 313, first, only the silicon oxide layer 305 is removed by using a photolithography technique and a dry-etching technique. At this time, the silicon nitride layer 304 can be also used as an etching stopper. Next, the dry etching is once stopped at the moment when the silicon nitride layer 304 is exposed, and next, the silicon nitride layer 304 is removed by a dry etching in a condition of removing the silicon nitride layer 304.

In the present embodiment, by performing such a two-step dry etching, the contact hole 313 can be provided with suppressing the amount of etching the phase-change material layer 302 to minimum.

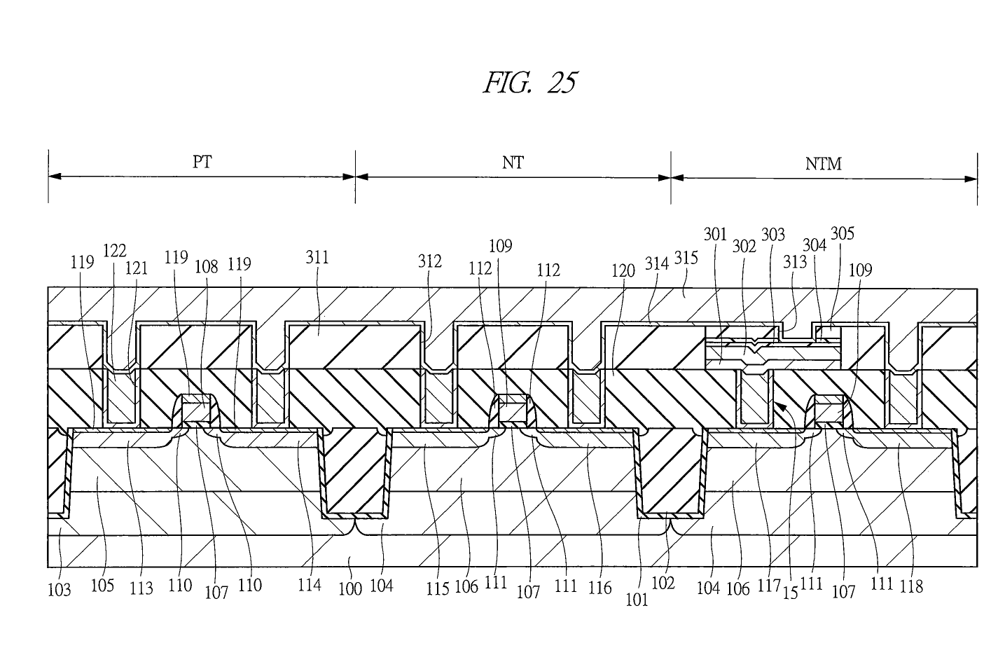

Subsequently, as shown in FIG. 25, a barrier metal film 314 formed of, for example, titanium nitride is deposited in the inside of the contact holes 312 and 313 and on the interlayer insulator 311, followed by depositing an electric conductive material film 315 formed of, for example, tungsten so as to fill the inside of the contact holes 312 and 313. The deposition of titanium nitride is desired to use a sputtering method capable of processing in a lower temperature than that of a CVD, and the deposition of tungsten is desired to use a CVD having a good filling property.

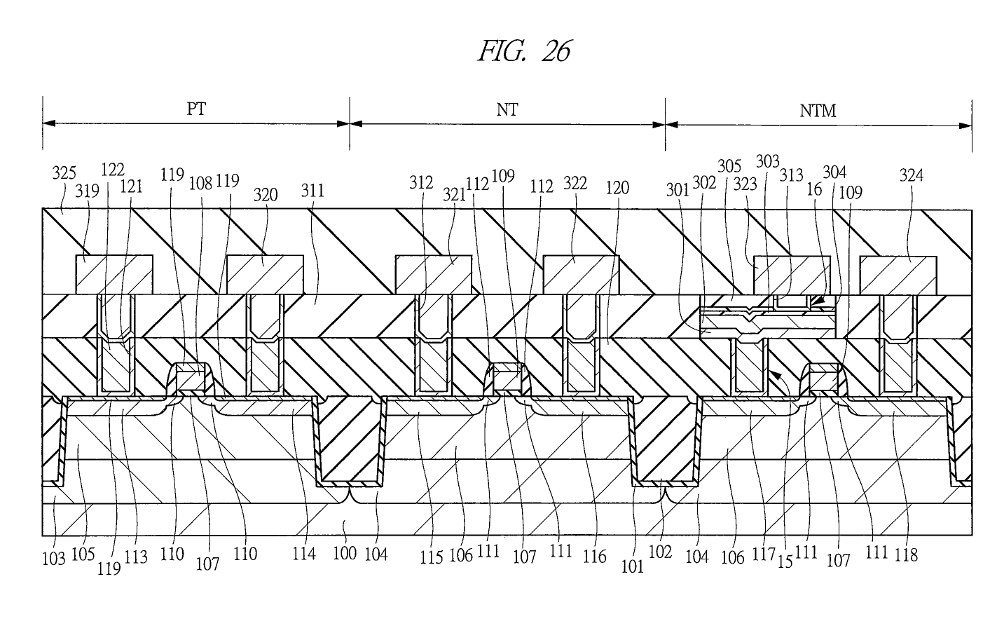

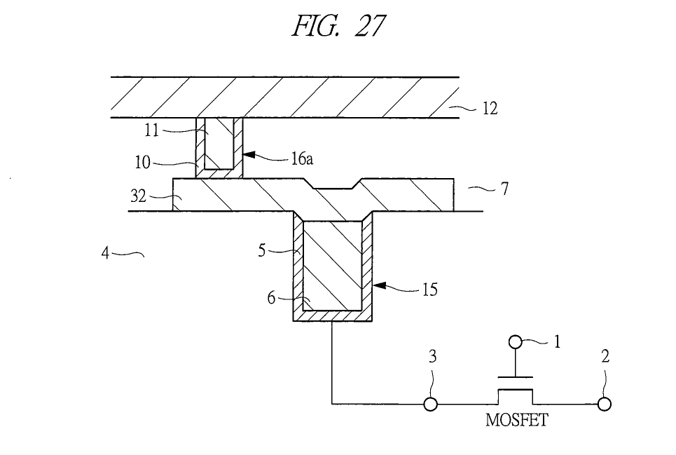

Subsequently, as shown in FIG. 26, unnecessary parts of the electric conductive material film 315 and the barrier metal film 314 are removed by a CMP technique until the silicon oxide layer 305 is exposed, so that the interlayer insulator 311 is planarized, and also the upper-electrode plug 16 including the barrier metal film 314 and the electric conductive material film 315 is formed in the contact hole 313. Note that, a diameter of the upper-electrode plug 16 is, for example, 160 nm.

Subsequently, a metal layer formed of, for example, aluminum is deposited on the main surface of the semiconductor substrate 100, and then, the metal layer is subjected to a patterning process, so that wiring layers corresponding to respective terminals are formed. That is, the patterned metal layers become a drain line 319 of the p-type MOSFET, a source line 320 of the p-type MOSFET, a drain line 321 of the n-type MOSFET, a source line 322 of the n-type MOSFET, a bit line 323 to be connected to the upper-electrode plug 16 of the phase-change memory device, and a source line 324 of the n-type MOSFET configuring the phase-change memory device, respectively.

Next, an interlayer insulator 325 formed of a silicon oxide film is deposited on the main surface of the semiconductor substrate 100 by using, for example, a CVD method. In this manner, the phase-change memory device according to the embodiment of the present invention can be formed on a CMOS-LSI. Note that, while the wiring layer is formed with not only one layer but normally two or three layers, only one layer has been disclosed in the present embodiment to avoid a complication of drawings.

### Fifth Embodiment

The first embodiment has described the case where the resistor device which configures the phase-change memory device has the bottom-electrode plug, the electric conductive material layer, the phase-change material layer, and the upper-electrode plug; and the phase-change material layer is provided between the electric conductive material layer and the upper-electrode plug. Meanwhile, in the present embodiment, there will be described a case where the electric conductive material layer is not used, and a bottom-electrode plug is in contact with a phase-change material layer. Note that, when the other configurations and the like are same with the first embodiment, the descriptions of the same may be omitted.

FIG. 27 is an explanatory diagram of a semiconductor device having a phase-change memory device according to the present embodiment of the present invention, and schematically shows a cross section of a resistor device that is provided on a semiconductor substrate and electrically connected to an n-type MOSFET. Note that, in FIG. 27, the MOSFET is depicted by a symbol for simplicity.

The phase-change memory device has: the bottom-electrode plug 15 that is buried in the interlayer insulator 4 that is provided on a main surface of the semiconductor substrate; a phase-change material layer 32 that is provided on an upper portion of the bottom-electrode plug 15 and on the interlayer insulator 4; and an upper-electrode plug 16a that is provided on the phase-change material layer 32. The bottom-electrode plug 15 and the upper-electrode plug 16a which configure the phase-change memory device are provided at respective different positions in a plane of the semiconductor substrate, and a contact area between the upper-electrode plug 16a and the phase-change material layer 32 is smaller than a contact area between the bottom-electrode plug 15 and the phase-change material layer 32. For example, compared to a diameter of the bottom-electrode plug 15 is 180 nm, a diameter of the upper-electrode plug 16a is 30 to 50 nm.

Here, in a manufacturing method of a semiconductor device according to the present embodiment, for example, when the second embodiment is used, the electric conductive material layer 123 is not formed in the step described in FIG. 6, and, the contact area between the upper-electrode plug 16 and the phase-change material layer 32 can be smaller than the contact area between the bottom-electrode plug 15 and the phase-change material layer 32 when patterning is performed to the electric conductive material layer 126 in the step described in FIG. 8.

Also in a structure of the phase-change memory device according to the present embodiment, an electrode forming a contact surface with the phase-change material layer 32 and having a contact surface to serve as a heat-generating portion is the upper-electrode plug 16a that includes the barrier metal film 10 and the electric conductive material film 11. The phase-change material layer 32 is provided between the upper-electrode plug 16a and the bottom-electrode plug 15, and a contact area between the upper-electrode plug 16a and the phase-change material layer 32 in an in-plane direction of the semiconductor substrate is smaller than a contact area between the bottom-electrode plug 15 and the phase-change material layer 32. In this manner, the upper-electrode plug 16a can have the contact surface to serve as the heat-generating portion. Also, a rewrite portion (phase-change region) in the phase-change material layer 32 is on the upper-electrode plug 16a side, so that a resistance value of the phase-change material layer 32 is changed by a phase change.

In this manner, since a pointed portion does not occur to the upper-electrode plug 16a in contact with the phase-change material layer 32, the bias of the constituent element as described with reference to FIG. 2 becomes less prone to occur. Therefore, a deterioration of an original characteristic can be prevented, thereby improving reliability of the semiconductor device. That is, since a current concentration to the pointed portion of the electrode that has the contact surface to serve as the heat-generating portion can be reduced, it can be expected that the bias of the component element which configures the phase-change material can be suppressed. In this manner, a stable phase-change memory device that has a small characteristic variation can be realized.

In the foregoing, the invention made by the inventor of the present invention has been concretely described based on the embodiments. However, it is needless to say that the present invention is not limited to the foregoing embodiments and various modifications and alterations can be made within the scope of the present invention.

For example, the above-described embodiments have been described the case where In (indium) is added to the chalcogenide material formed of Ge(germanium)-Sb(antimony)-Te(tellurium). Meanwhile, the additive element can be at least one kind of element that is selected from a group including, for example, Ga (gallium), Al (aluminum), Zn (zinc), Cd (cadmium), Pb (lead), Si (silicon), V (vanadium), Nb (niobium), Ta (tantalum), Cr (chromium), Mo (molybdenum), W (tungsten), Ti (titanium), Fe (iron), Co (cobalt), Ni (nickel), Pt (platinum), Pd (palladium), Y (yttrium), and Eu (europium).

The present invention can be widely used in a manufacturing industry of a semiconductor device, and more particularly, a semiconductor device having a non-volatile memory that is configured with a phase-change material.

What is claimed is:

1. A semiconductor device comprising:
a first electrode plug buried in an insulator that is provided on a main surface of a semiconductor substrate;
an electric conductive material layer provided on an upper portion of the first electrode plug and on the insulator;
a phase-change material layer provided on the electric conductive material layer; and
a second electrode plug provided on the phase-change material layer, wherein
the first electrode plug and the second electrode plug are provided at respective different positions in a plane of the semiconductor substrate.

2. The semiconductor device according to claim 1, wherein
the first electrode plug and the second electrode plug do not overlap to each other in the plane of the semiconductor substrate.

3. The semiconductor device according to claim 1, wherein
a contact area between the second electrode plug and the phase-change material layer is smaller than a contact area between the electric conductive material layer and the phase-change material layer in an in-plane direction of the semiconductor substrate.

4. The semiconductor device according to claim 1, wherein
the phase-change material layer has a resistance value that is changed by a phase-change on the second electrode plug side.

5. The semiconductor device according to claim 1, wherein
the phase-change material layer is formed by adding indium to a chalcogenide material formed of germanium, antimony, and tellurium.

6. The semiconductor device according to claim 1, wherein
an interface layer is provided between the phase-change material layer and the second electrode plug.

7. The semiconductor device according to claim 1, wherein
a recess is provided on an upper portion of the first electrode plug.

8. A semiconductor device comprising:
a first electrode plug buried in an insulator that is provided on a main surface of a semiconductor substrate;
a phase-change material layer provided on an upper portion of the first electrode plug and on the insulator; and
a second electrode plug provided on the phase-change material layer, wherein
the first electrode plug and the second electrode plug are provided at respective different positions in a plane on the semiconductor substrate, and
a contact area between the second electrode plug and the phase-change material layer is smaller than a contact area between the first electrode plug and the phase-change material layer.

9. The semiconductor device according to claim 8, wherein
an interface layer is provided between the phase-change material layer and the second electrode plug.

10. A manufacturing method of a semiconductor device comprising the steps of:
(a) forming an insulator on a main surface of a semiconductor substrate;
(b) forming a first contact hole in the insulator;
(c) burying a first electric conductive material in the first contact hole;
(d) planarizing the insulator by a CMP technique, and also forming a first electrode plug formed of the first electric conductive material in the first contact hole after the step (c);
(e) forming a first electric conductive material layer on an upper portion of the first electrode plug and on the insulator after the step (d);
(f) forming a phase-change material layer on the first electric conductive material layer after the step (e); and
(g) forming a second electrode plug on the phase-change material layer and at a different position from the first electrode plug in a plane of the semiconductor substrate.

11. The manufacturing method of a semiconductor device according to claim 10, wherein
the step (g) comprises the steps of
(g11) forming a second electric conductive material layer on the phase-change material layer followed by patterning the second electric conductive material layer, and wherein
the second electrode plug is formed of the patterned second electric conductive material layer.

12. The manufacturing method of a semiconductor device according to claim 10, wherein
the step (g) comprises the steps of:
(g21) forming a silicon oxide layer on the phase-change material layer followed by forming a silicon nitride layer on the silicon oxide layer;
(g22) forming a second contact hole in the silicon nitride layer and the silicon oxide layer; and
(g23) burying a second electric conductive material in the second contact hole, wherein
the second electrode plug is formed of the second electric conductive material buried in the second contact hole, and
the second contact hole is formed in the silicon oxide layer by using hydrofluoric acid in the step (g22).

13. The manufacturing method of a semiconductor device according to claim 10, wherein
the step (g) comprises the steps of:
(g31) forming a silicon nitride layer on the phase-change material layer followed by forming a silicon oxide layer on the silicon nitride layer;
(g32) forming a second contact hole in the silicon oxide layer and the silicon nitride layer; and
(g33) burying a second electric conductive material in the second contact hole, and wherein
the second electrode plug is formed of the second electric conductive material buried in the second contact hole, and
the silicon oxide layer and the silicon nitride layer are subjected to dry etching in respective different conditions to form the second contact hole in the silicon oxide layer and the silicon nitride layer in the step (g32).

14. The manufacturing method of a semiconductor device according to claim 10 comprising a step of forming an interface layer on the phase-change material layer between the step (f) and the step (g), wherein
the second electrode plug is formed on the phase-change material layer interposing the interface layer in the step (g).

15. The manufacturing method of a semiconductor device according to claim 10, wherein
the phase-change material layer is formed by adding indium to a chalcogenide material formed of germanium, antimony, and tellurium in the step (f).
